(19) United States
(12) Patent Application Publication
(10) Pub. No.: US 2026/0123331 A1
(43) Pub. Date: Apr. 30, 2026

(54) SEMICONDUCTOR PROCESSING APPARATUS, SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Che Wei Yang, New Taipei City (TW); Cheng-Yuan Tsai, Hsin-Chu county (TW); Hau-Yi Hsiao, Chiayi City (TW); Kuo-Ming Wu, Tainan City (TW); Sheng-Chau CHEN, Tainan City (TW); Chung-Yi Yu, Hsin-Chu (TW)

(73) Assignee: Taiwan Semiconductor Manufacturing Company, Ltd., Hsinchu (TW)

(21) Appl. No.: 18/925,038

(22) Filed: Oct. 24, 2024

(51) Int. Cl. H01L 21/67; H01L 21/56; H01L 21/687; H01L 23/00; H01L 23/29; H01L 23/31; H01L 25/065

(52) U.S. Cl. CPC H10P 72/0441; H10P 72/7604; H10W 74/01; H10W 74/141; H10W 90/00; H10W 74/43; H10W 74/47; H10W 80/312; H10W 80/327; H10W 90/26; H10W 90/792

(57) ABSTRACT

A semiconductor processing apparatus includes a supporting platform configured to support a wafer stack structure comprising a first wafer bonded over a second wafer, and an injection device movably disposed above the supporting platform. The injection device includes an edge detector configured to locate a beveled edge between the first wafer and the second wafer, and a plasma injector coupled to the edge detector and configured to perform a plasma treatment over the beveled edge between the first wafer and the second wafer.

### BACKGROUND

Semiconductor chips used in electronic devices comprise a semiconductor die mounted on a carrier or a substrate. In an effort to increase the density and functionality of a semiconductor chip, attempts have been made to create 3D-ICs, or three-dimensional integrated circuits. Generally, 3D-ICs comprise a plurality of semiconductor dies stacked upon each other, such as one semiconductor die bonded on top of another semiconductor die. Electrical connections electrically couple contact pads on each of the stacked semiconductor dies to external contacts. The dies may include different functionality or simply increase the density of a single functionality, such as a memory.

Generally, attempts at creating 3D-ICs have included bonding a first wafer on which a plurality of dies has been formed to a second wafer, also on which a plurality of dies has been formed. The wafers are aligned such that the dies of one wafer are aligned with dies of the other wafer. As mentioned above, the dies of the wafers may have a different function or provide increased density for a single type of function, such as memory. Once bonded, a thinning process is typically performed to form electrical connections, typically by exposing a through silicon via that is electrically coupled to the bottom wafer. During the thinning process, however, the wafer often cracks and chips because the edges of the wafer are unsupported.

One attempt at preventing cracks and chips during the thinning process involved etching a notch along the periphery of the wafer to be thinned. Another attempt involved sawing an edge of the wafer to be thinned off, and then thinning the wafer. These attempts, however, reduce the wafer size and often include additional timely processes. Furthermore, these attempts may also require specialized equipment or may be incompatible with processes used by some fabricators.

Accordingly, there is a need for an efficient and effective method to create a stacked wafer configuration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which a semiconductor processing apparatus described herein may be implemented.

FIG. 2 is a diagram of an example implementation of formation of a wafer stack structure described herein.

FIG. 3 is a schematic view of intermediate stages in the manufacturing of a semiconductor package according to some exemplary embodiments of the present disclosure.

FIG. 4 illustrates a partial magnified view of the wafer stack structure according to some exemplary embodiments of the present disclosure.

FIG. 5 to FIG. 11 illustrate cross sectional views of intermediate stages in the manufacturing of a semiconductor package according to some exemplary embodiments of the present disclosure.

FIG. 12 illustrates a cross sectional view of a plasma injector according to some exemplary embodiments of the present disclosure.

FIG. 13 illustrates a side view of a semiconductor processing apparatus according to some exemplary embodiments of the present disclosure.

FIG. 14 illustrates a side view of a semiconductor processing apparatus according to some exemplary embodiments of the present disclosure.

FIG. 15 illustrates a side view of a semiconductor processing apparatus according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a wafer stack structure, such as a wafer-on-wafer (WoW) structure, may include a single material (e.g., a silicon oxynitride (SiON) material) that is shared along a bond interface between co-facing surfaces of two integrated circuit dies that are joined together. In some cases, lateral stresses present throughout such a bond interface may cause a warpage of the wafer stack structure. Additionally, such a bond interface may possess a rigidity characteristic that fails to sufficiently dampen vibrations and/or reduce stresses along the bond interface during an operation that thins the wafer stack structure (or die stacked structure). In such cases, the bond interface may crack or peel during the thinning operation, cause the two integrated circuit dies to separate, and render the stacked die product to be non-functional. Further, and to mitigate such warpage, cracking, and/or peeling, one or more additional processing operations may be implemented, such as a trimming operation along a perimeter of two or more semiconductor substrates (i.e., wafers) that are joined as part of forming the wafer stack structure.

Some implementations described herein provide techniques and apparatuses for forming a wafer stack structure including two or more semiconductor wafers. A bond interface between two semiconductor wafers that are included in the wafer stack structure includes a layered structure. A plasma treatment is performed on the beveled edge defined by the curvy bonding interface between two semiconductor wafers. A sealant material is then dispended over the plasma treated beveled edge of the two wafers. The plasma treatment can cause the dielectric on the beveled edge of the wafers to have a dangling bond at the treated surfaces, so the sealant material applied later on can be bonded to the dangling bond and/or react with the treated surfaces to increase bonding strength. The sealant material may reduce lateral stresses throughout the bond interface to reduce a likelihood of warpage of the two wafers. Additionally, the sealant material can increase adhesive properties and/or increased vibration dampening properties. The reduction in lateral stresses, the increased adhesive properties, and/or the vibration dampening properties may reduce a likelihood of the bond interface cracking or peeling during a thinning operation that thins one or more of the two wafers.

In this way, a yield of a wafer stack structure can be increased. Additionally, or alternatively and in some implementations, a trimming operation along a perimeter of semiconductor substrates joined as part of forming the wafer stack structure may be eliminated. By increasing the yield of the wafer stack structure (also the stacked die product fabricated therefrom) and eliminating the trimming operation, a consumption of resources for manufacturing a volume of the stacked die product (e.g., semiconductor manufacturing processing tools, raw materials, manpower, and/or computing resources) may be reduced.

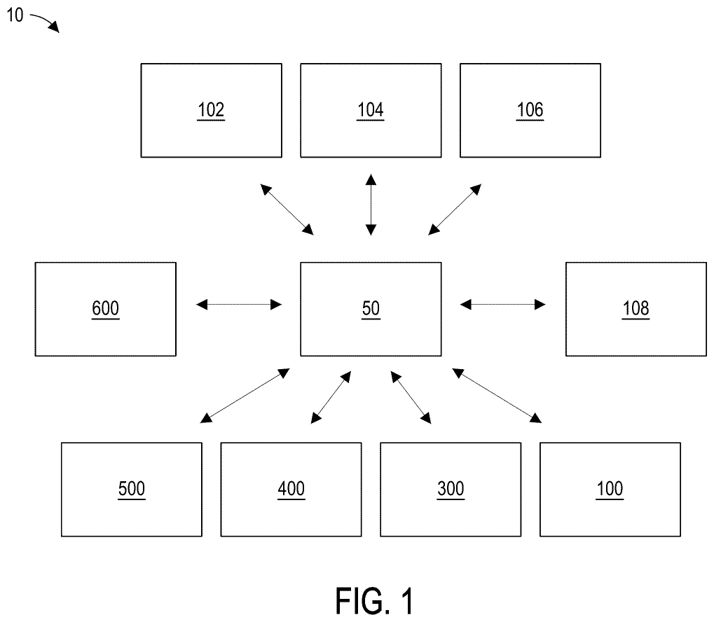

FIG. 1 is a diagram of an example environment in which a semiconductor processing apparatus described herein may be implemented. As shown in FIG. 1, a semiconductor processing system (i.e. environment) 10 includes a combination of semiconductor processing apparatuses. For example, the semiconductor processing system 10 may includes a deposition apparatus 102, an exposure apparatus 104, an etch apparatus 106, a bonding apparatus 108, an injection apparatus 100, a planarization apparatus 300, a connection apparatus 400, an automated test equipment (ATE) apparatus 500, a singulation apparatus 600, a transport apparatus 50, or the like. The semiconductor processing apparatuses of example environment may be included in one or more facilities, such as a semiconductor clean or semi-clean room, a semiconductor foundry, a semiconductor processing facility, an outsourced assembly and test (OSAT) facility, and/or a manufacturing facility, among other examples.

The deposition apparatus 102 is a semiconductor processing apparatus that is capable of depositing various types of materials onto a substrate. In some implementations, the deposition apparatus 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool apparatus 102 includes a physical vapor deposition (PVD) tool, such as a sputtering tool or another type of PVD tool. In some implementations, the semiconductor processing system 10 includes a plurality of types of deposition apparatus 102.

The exposure apparatus 104 is a semiconductor processing apparatus that is capable of exposing a photoresist layer to a radiation source, such as an ultraviolet light (UV) source (e.g., a deep UV light source, an extreme UV (EUV) light source, and/or the like), an x-ray source, an electron beam source, and/or another type of radiation source. The exposure apparatus 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure apparatus 104 includes a scanner, a stepper, or a similar type of exposure apparatus.

The etch apparatus 106 is a semiconductor processing apparatus that is capable of etching various types of materials of a substrate, wafer, or semiconductor device. For example, the etch apparatus 106 may include a wet etching tool, a dry etching tool, and/or another type of etching tool. A wet etching tool may include a chemical etching tool or another type of wet etching tool that includes a chamber filled with an etchant. The substrate may be placed in the chamber for a particular time period to remove particular amounts of one or more portions of the substrate. A dry etching tool may include a plasma etching tool, a laser etching tool, a reactive ion etching tool, or a vapor phase etching tool, among other examples. A dry etching tool may remove one or more portions of the substrate using a sputtering technique, a plasma-assisted etch technique (e.g., a plasma sputtering technique or another type of technique involving the use of an ionized gas to isotropically or directionally etch the one or more portions), or another type of dry etching technique.

The bonding apparatus 108 is a semiconductor processing apparatus that is capable of bonding two or more wafers (or two or more semiconductor substrates, or two or more semiconductor devices) together. For example, the bonding apparatus 108 may include a eutectic bonding apparatus that is capable of forming a eutectic bond between two or more wafers. In these examples, the bonding apparatus 108 may heat the two or more wafers to form a eutectic system between the materials of the two or more wafers.

The injection apparatus 100 is a semiconductor processing apparatus that is configured to inject plasma gas for a plasma treatment during fabrication of a semiconductor device package. For example, the injection apparatus 100 may include a plasma injector that inject plasma gas over the beveled edge between the first wafer and the second wafer as part of a multi semiconductor wafer stacking process. In some embodiments, injection apparatus 100 may further include a pressurized jet nozzle that dispenses one or more materials over the beveled edge between the first wafer and the second wafer as part of a multi semiconductor substrate stacking process. The components of the injection apparatus 100 will be described in more detail hereinafter.

The planarization apparatus 300 is a semiconductor processing apparatus that is capable of polishing or planarizing various layers of a wafer or semiconductor device. For example, the planarization apparatus 300 may include a planarization tool such as a chemical mechanical planarization (CMP) apparatus and/or another type of planarization apparatus that configured to perform a thinning process over the first wafer (e.g. upper wafer). The planarization apparatus may thin or flatten a surface of a semiconductor device with a combination of chemical and mechanical forces (e.g., chemical etching and free abrasive polishing). The planarization apparatus 300 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The connection apparatus 400 is a semiconductor processing apparatus that is capable of forming connection structures (e.g., electrically-conductive structures). The connection structures formed by the connection apparatus 400 may include a wire, a stud, a pillar, a bump, or a solder ball, among other examples. The connection structures formed by the connection apparatus 400 may include materials such as a gold (Au) material, a copper (Cu) material, a silver (Ag) material, a nickel (Ni) material, a tin (Sn) material, or a palladium (Pd) material, among other examples. The connection apparatus 400 may include a bumping tool, a wire-bond tool, or a plating tool, among other examples.

The ATE apparatus 500 is a semiconductor processing apparatus that is capable of testing a quality and a reliability of one or more integrated circuit dies and/or a semiconductor package (e.g., the one or more integrated circuit dies after encapsulation). The ATE apparatus 500 may perform wafer testing operations, known good die (KGD) testing operations, and/or semiconductor die package testing operations, among other examples. The ATE apparatus 500 may include a parametric tester tool, a speed tester tool, and/or a burn-in tool, among other examples. Additionally, or alternatively, the ATE apparatus 500 may include a prober tool and/or probe card tooling, among other examples.

The singulation apparatus 600 is a semiconductor processing apparatus that is capable of singulating (e.g., separating, removing) one or more integrated circuit dies from a wafer. For example, the singulation apparatus 600 may include a dicing tool, a sawing tool, and/or or a laser tool that cuts the one or more integrated circuit dies from the wafer, among other examples.

The transport apparatus 50 is a semiconductor processing apparatus capable of transporting work-in-process (WIP) between the semiconductor processing apparatuses 102-118. The transport apparatus 50 may be configured to accommodate one or more transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples. The transport apparatus 50 may also be configured to transfer and/or combine WIP amongst transport carriers. The transport apparatus 50 may include a pick-and-place tool, a conveyor tool, a robot arm tool, an overhead hoist transport (OHT) tool, an automated materially handling system (AMHS) tool, and/or another type of tool. In some implementations, the system 10 includes a plurality of types of such tools as part of the transport apparatus 50.

The number and arrangement of semiconductor processing apparatuses shown in FIG. 1 are provided as one or more examples. In practice, there may be additional semiconductor processing apparatuses, different semiconductor processing apparatuses, or differently arranged semiconductor processing apparatuses than those shown in FIG. 1. Furthermore, two or more semiconductor processing apparatuses shown in FIG. 1 may be implemented within a single apparatus set, or an apparatus set shown in FIG. 1 may be implemented as multiple, distributed semiconductor processing tools. Additionally, or alternatively, one or more semiconductor processing apparatuses of the system 10 may perform one or more functions described as being performed by another apparatus set of the system 10.

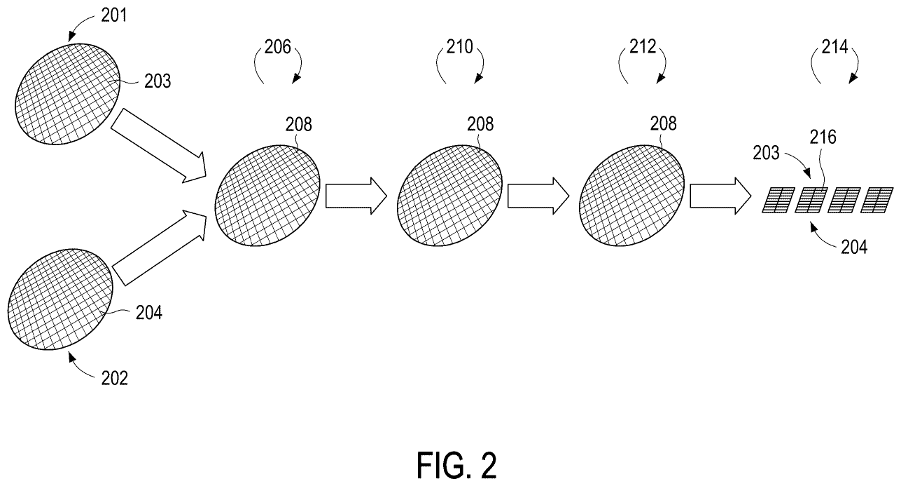

FIG. 2 is a diagram of an example implementation of formation of a wafer stack structure described herein. The semiconductor package 200 may correspond to a “Wafer-on-Wafer” (WoW) technique used to form a three-dimensional integrated circuit die (3DIC) structure, among other examples. The semiconductor package 200 may use one or more semiconductor processing apparatuses and/or the transport apparatus of FIG. 1 to form the die stack structure.

Referring to FIG. 2, as shown, a first wafer 201 may include a plurality of integrated circuit dies 203 and a second wafer 202 may include a plurality of integrated circuit dies 204. The integrated circuit dies 203 and 204 may be formed using a series of deposition operations by the deposition apparatus 102, a series of patterning operations by the exposure apparatus 104, and a series of etch operations by the etch apparatus 106, among other examples.

A bonding operation 206 (e.g., a bonding operation by the bonding apparatus 108, among other examples) may align the integrated circuit dies 203 and 204 and bond the first wafer 201 and the second wafer 202 to form a wafer stack structure 208. As a result of the bonding operation 206, integrated circuity of the integrated circuit dies 203 and 204 may be electrically connected for signaling purposes (e.g., inputs/output signaling, clocking or timing signaling, and/or power signaling, among other examples). The bonding operation 206 may include a eutectic bonding operation, a hybrid bonding operation, and/or another type of bonding operation.

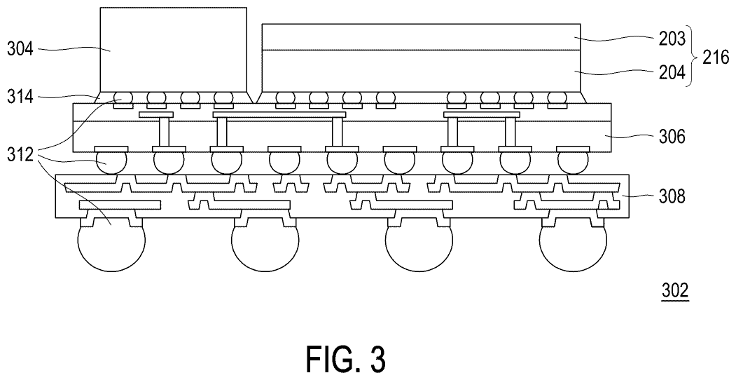

To conserve space in a final semiconductor package 200, a thinning operation 210 (e.g., a thinning operation by the planarization apparatus 300) may be performed to a top substrate of the wafer stack structure 208. In some implementations, and as described in greater detail in connection with FIGS. 3-10 and elsewhere herein, a plasma treatment and a sealant material dispensing may be performed on the wafer stack structure 208 prior to the bonding operation 210. The sealant material may improve a robustness of the wafer stack structure 208 during the thinning operation 210 and/or subsequent operations performed to the wafer stack structure 208. For example, and by improving the robustness of the wafer stack structure 208, a likelihood of defects and/or yield loss within the stack of semiconductor substrates 208 due to trim-loss, trim wall exposure, and/or trim peeling that is inherent to a trimming operation may be reduced. Additionally, or alternatively and in some implementations, such a trimming operation is eliminated.

A bumping operation 212 (e.g., a bumping operation by the connection apparatus 400, among other examples) may form connection structures (e.g., solder balls, among other examples) on pads of integrated circuit dies of a top wafer (e.g., the integrated circuit dies 203 of the first wafer 201). Such connection structures may be used for a testing operation and/or a packaging operation that encapsulates a die stack structure 216 from the wafer stack structure 208.

A downstream series of operations 214 may include a testing operation and a dicing operation to test a die stack structure 216 (e.g., the integrated circuit die 203 bonded to the integrated circuit die 204) and extract the die stack structure 216 from the stack of semiconductor substrates. The testing operation (e.g., a testing operation by the ATE apparatus 500, among other examples) may ensure a quality of the bonding operation 210 and/or a quality of the integrated circuit dies included in the wafer stack structure 208 (e.g., the integrated circuit die 203 and/or the integrated circuit die 204, among other examples). The testing operation may include a functionality test, a parametric test, and/or a reliability test, among other examples. The dicing operation to extract the die stack structure 216 from the wafer stack structure 208 may be performed by the singulation apparatus 600, among other examples. As indicated above, FIG. 2 is provided as an example. Other examples may differ from what is described with regard to FIG. 2.

FIG. 3 is a diagram of an implementation of an example semiconductor package including a die stack structure described herein. It is noted that the semiconductor package 302 shown in FIG. 3 merely illustrates one of the implementations of semiconductor packages that includes the die stacked structure 216 formed from the wafer stack structure 208. In some embodiments, the semiconductor package 302 includes the die stack structure 216 (e.g., the integrated circuit die 203 bonded to the integrated circuit die 204) and an integrated circuit die 304. As examples, the integrated circuit die 203 may correspond to a first system on chip (SoC) integrated circuit die and the integrated circuit die 204 may correspond to a second SoC integrated circuit die. Additionally, or alternatively, the integrated circuit die 304 may correspond to a high bandwidth memory (HBM) die, such as a dynamic random access memory (DRAM) IC die.

The semiconductor package 302 may include an interposer 306 having one or more layers of electrically-conductive traces. The electrically-conductive traces of the interposer 306 may include one or more materials such as a gold (Au) material, a copper (Cu) material, a silver (Ag) material, a nickel (Ni) material, a tin (Sn) material, or a palladium (Pd) material, among other examples. The interposer 306 may further include one or more layers of a dielectric material, such as a ceramic material or a silicon material, among other examples. In some implementations, the interposer 306 corresponds to a PCB including layers of a glass-reinforced epoxy laminate material and/or a pre-preg material (e.g., a composite fiber/resin/epoxy material), among other examples. Additionally, or alternatively, one or more layers of the interposer 306 may include a buildup film material.

The semiconductor package 302 may further include a substrate 308 having one or more layers of electrically-conductive traces. The electrically-conductive traces of the substrate 308 may include one or more materials such as a gold (Au) material, a copper (Cu) material, a silver (Ag) material, a nickel (Ni) material, a tin (Sn) material, or a palladium (Pd) material, among other examples. The substrate 308 may further include one or more layers of a dielectric material, such as a ceramic material or a silicon material, among other examples. In some implementations, the substrate corresponds to a PCB including layers of a glass-reinforced epoxy laminate material and/or a pre-preg material (e.g., a composite fiber/resin/epoxy material), among other examples. Additionally, or alternatively, one or more layers of the substrate 308 may include a buildup film material.

The semiconductor package 302 may further include connection structures 312. Examples of the connection structures 312 include a stud, a pillar, a bump, and/or a solder ball. The connection structures 312 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

A portion of the connection structures 312 may connect the die stack structure 216 and/or the integrated circuit die 304 with the interposer (e.g., the stacked die product 216 and/or the integrated circuit die 304 are attached to the interposer 306 using one or more of the connection structures 312). Additionally, or alternatively, another portion of the connection structures 312 may connect the interposer with the substrate 308. Additionally, or alternatively, another portion of the connection structures 312 may be included to connect the substrate to a system level PCB. In some implementations, the connection structures 312 provide one or more electrical connections for transmitting and/or exchanging signals within the semiconductor die package 302. Additionally, or alternatively and in some implementations, the connection structures 312 provide one or more mechanical connections for attachment purposes and/or spacing purposes). Additionally, or alternatively and in some implementations, one or more of the connection structures 312 provide both electrical and mechanical connections.

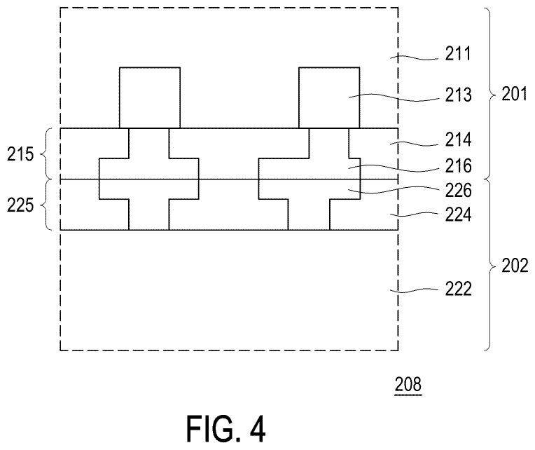

FIG. 4 illustrates a partial magnified view of the wafer stack structure according to some exemplary embodiments of the present disclosure. As shown in the detail of FIG. 4, magnified view of the wafer stack structure 208, the first wafer 201 and the second wafer 202 are shown being bonded in accordance with an embodiment of the present disclosure. The first wafer 201 and the second wafer 202 include a first semiconductor substrate 211 and a second semiconductor substrate 222 respectively, with electronic circuitry (not shown) formed thereon. The first semiconductor substrate 211 and the second semiconductor substrate 222 may each include bulk silicon, doped or undoped, or an active layer of a semiconductor-on-insulator (SOI) substrate. Generally, an SOI comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

The circuitry formed on the substrate may be any type of circuitry suitable for a particular application. In an embodiment, the circuitry includes electrical devices formed on the substrate with one or more dielectric layers overlying the electrical devices. Metal layers may be formed between dielectric layers to route electrical signals between the electrical devices. Electrical devices may also be formed in the one or more dielectric layers.

For example, the circuitry may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of the present invention and are not meant to limit the present invention in any manner. Other circuitry may be used as appropriate for a given application.

In some embodiments, the first wafer 201 and the second wafer 202 include a first interconnect layer 215 and a second interconnect layer 225, respectively, formed thereon. The first interconnect layer 215 includes contacts 216 formed in one or more dielectric layers 214. Correspondingly, the second interconnect layer 225 includes contacts 226 formed in one or more dielectric layers 224. Generally, the one or more dielectric layers 214, 224 may be formed, for example, of a low-K dielectric material, silicon oxide, phosphosilicate glass (PSG), borophosphosilicate glass (BPSG), fluorinated silicate glass (FSG), or the like, by any suitable method known in the art. In an embodiment, the one or more dielectric layers 214, 224 include an oxide that may be formed by chemical vapor deposition (CVD) techniques using tetra-ethyl-ortho-silicate (TEOS) and oxygen as a precursor. Other materials and processes may be used. It should also be noted that the dielectric layers 214, 224 may each include a plurality of dielectric layers, with or without an etch stop layer formed between dielectric layers.

The contacts 216, 226 may be formed in the dielectric layers 214, 224 respectively by any suitable process, including photolithography and etching techniques. Generally, photolithography techniques involve depositing a photoresist material, which is masked, exposed, and developed to expose portions of the dielectric layers 214, 224 that are to be removed. The remaining photoresist material protects the underlying material from subsequent processing steps, such as etching. In the preferred embodiment, photoresist material is utilized to create a patterned mask to define contacts 216, 226. The etching process may be an anisotropic or isotropic etch process, but preferably is an anisotropic dry etch process. After the etching process, any remaining photoresist material may be removed. Processes that may be used to form the contacts 216, 226 include single and dual damascene processes.

The contacts 216, 226 may be formed of any suitable conductive material, but is preferably formed of a highly-conductive, low-resistive metal, elemental metal, transition metal, or the like. Furthermore, the contacts 216, 226 may include a barrier/adhesion layer to prevent diffusion and provide better adhesion between the contacts 216, 226 and the dielectric layers 214, 224.

It should be noted that in the embodiment illustrated in FIG. 1, the contacts 226 formed on the first wafer 201 may connect to any type of semiconductor structure (not shown), such as transistors, capacitors, resistors, or the like, or an intermediate contact point, such as a metal interconnect or the like.

Also illustrated in FIG. 4 are through-silicon vias (TSVs) 213 formed in the first semiconductor substrate 211. The TSVs 213 may be formed of any suitable conductive material, but are preferably formed of a highly-conductive, low-resistive metal, elemental metal, transition metal, or the like. For example, in an embodiment the TSVs are filled with Cu, W, or the like. The TSVs 213 are electrically coupled to respective ones of the contacts 216 on the first wafer 201. As will be discussed below, the first wafer 201 will be thinned, thereby exposing the TSVs 213.

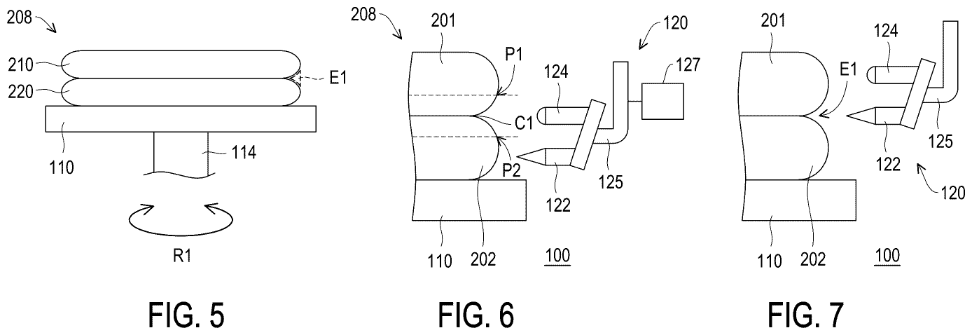

FIG. 5 to FIG. 11 illustrate cross sectional views of intermediate stages in the manufacturing of a semiconductor package according to some exemplary embodiments of the present disclosure. Referring to FIG. 5, in accordance with some embodiments of the disclosure, a bonding process is performed to the first wafer 201 and the second wafer 202 so the first wafer 201 is bonded over the second wafer 202 and form the wafer stacking structure 208. The bonding process may include any suitable bonding procedure for the specific application and materials. For example, direct bonding, metal diffusion, anodic, oxide fusion bonding, and the like bonding methods may be performed. In an embodiment, a conductive metal or metal alloy, such as Cu, W, CuSn, AuSn, InAu, PbSn, or the like, is utilized as a bonding material to directly bond contacts on the first wafer 104 to the corresponding contacts on the second wafer 106. In another embodiment, a polymer, such as bis-benzocyclobutene (BCB), epoxy, an organic glue, or the like, is utilized as a bonding material. In this embodiment, the bonding material may be applied to the dielectric layer 214, 224 of the first wafer 201 and/or the second wafer 202.

Referring to FIG. 5 and FIG. 6, in some embodiments, the semiconductor processing apparatus 100 may include a supporting platform 110 and an injection device 120. The first wafer 201 and the second wafer 202 are bonded together and placed on the supporting platform 110. The supporting platform 110 may include an electrostatic chuck and/or a clamp ring (not shown) to support and hold the wafer stack structure 208 during processing. In some embodiments, the supporting platform 110 may also have cooling and/or heating elements (not shown) to control the temperature of the supporting platform 110. In one embodiment, the supporting platform 110 may also provide backside gas to the wafer stack structure 208 to increase heat transfer between the wafer stack structure 208 and the supporting platform 110.

In some embodiments, the supporting platform 110 may be coupled to a rotation device, such as a rotating shaft 114 and a motor. The motor is coupled to the rotating shaft 114 to drive the supporting platform 110 and the wafer stack structure 208 to rotate around the rotating shaft 114 during processing. Rotation of the wafer stack structure 208 helps to provide uniform processing over the wafer stack structure 208.

Referring to FIG. 6, the injection device 120 is movably disposed above the supporting platform 110 and the injection device 120 includes an edge detector 124 and a plasma injector 122. The edge detector 124 is configured to locate a beveled edge E1 between the first wafer 201 and the second wafer 202, and the plasma injector 122 is coupled to the edge detector 204 and configured to perform a plasma treatment over the beveled edge E1 between the first wafer 201 and the second wafer 202. In some embodiments, the semiconductor processing apparatus 100 further includes a transfer mechanism 125 that is coupled to the injection device 120 to move the injection device 120 above the supporting platform 110. In some embodiments, the transfer mechanism 125 may include a robot arm that has multiple degree of freedom. In one embodiment, the transfer mechanism 125 may include a 5 degree of freedom (DOF) robot arm. To be more specific, the 5 DOF robot arm is a robotic arm that has five joints, including a manipulator, a servo-motor actuator, and corresponding arm components like the arm, the base, the wrist, etc., which can handle more movements due to the presence of more joints. However, the disclosure is not limited thereto. the transfer mechanism 125 may include a robot arm that has more or less degree of freedom.

In accordance with some embodiments of the disclosure, the beveled edge E1 is defined by an unfilled area between outer edges of the first wafer 201 and the second wafer 202. In detail, the edges of the first wafer 201 and the second wafer 202 are generally non-perpendicular, beveled, or rounded. In other words, the first wafer 201 includes a non-perpendicular rounded side surface connecting the upper surface and a lower surface being bonded to the second wafer 202. As a result, the wafer edges of the first wafer 201 is not supported by the second wafer 202 and may break off during a thinning process performed on the first wafer 201. Accordingly, a series of processes may be performed prior to the thinning process.

In some embodiments, the edge detector 124 includes an image sensor such as a charge-coupled device (CCD) camera for capturing the image of at least one portion of the beveled edge E1 by the charge-coupled technique. It is noted that the beveled edge E1 is roughly the area near the outer boundary of the wafer stack structure 208. In some embodiments, the edge detector 124 may further include an illuminant device for illuminating the at least one portion of the beveled edge E1 of the wafer stack structure 208. FIG. 6 is a simplified diagram illustrating a configuration of the plasma injector 122, the edge detector 124, the transfer mechanism 125, and the wafer stack structure 208 in accordance with some embodiments.

In some embodiments, the method for the edge detector (e.g., image sensor) 124 to locate the beveled edge E1 may include the following steps. Firstly, at least one image of the beveled edge E1 is captured by the image sensor 124. Then, a processor 127 coupled to the image sensor 124 identifies a first inflection point P1 of the first wafer 201 and a second inflection point P2 of the second wafer 202 according to the image captured by the image sensor 124. Herein, the processor 127 may be the processor of the semiconductor processing apparatus 100 or the processor built in the edge detector 124. Then, the processor 127 obtains a center C1 of the beveled edge E1 according to positions of the first inflection point P and the second inflection point P1. In detail, the slope profile of the first wafer 201, according to some embodiments, has an inflection point (i.e., turning point) P1 at or near the bonding surface (i.e., lower surface) of the first wafer 201. Similarly, the slope profile of the second wafer 202, according to some embodiments, has an inflection point (i.e., turning point) P2 at or near the bonding surface (i.e., upper surface) of the second wafer 202. In the embodiment, and the center C1 of the beveled edge E1 is at the middle point of the distance from the first inflection point P to the second inflection point P2. The region between the first inflection point P1 and the second inflection point P2 can be seen as the beveled edge E1, and the center C1 of the beveled edge E1 can be the alignment reference point for the subsequent processes to be applied to the beveled edge E1.

Then, referring to FIG. 7, the plasma injector 122 is positioned to perform a plasma treatment by injecting plasma gas toward the beveled edge E1. In some embodiments, after the edge detector 124 locates the beveled edge E1, the injection device 120 is moved by the transfer mechanism 125, so that a nozzle of the plasma injector 122 is aligned with the center C1 of the beveled edge E1. The plasma treatment can include using a plasma gas including clean dry air (CDA), nitrogen (N₂), oxygen (O₂), argon (Ar), hydrogen (H₂), the like or a combination thereof. A flow rate of the gas can be in a range from about 1 sccm to about 100,000 sccm. A pressure of the plasma treatment can be in a range from about 10 mTorr to about 100 mTorr, and a temperature of the plasma treatment can be in a range from about −20° C. to about 60° C. A power of the plasma generator of the plasma treatment can be in a range from about 10 W to about 1000 W. A frequency of the plasma generator can be about 13.56 MHz or greater for radio frequency (RF) plasma treatment, a frequency of the plasma generator can be range from about 1 kHz to about 600 kHz for medium frequency (MF) plasma treatment, and a frequency of the plasma generator can be range from about 1 GHz to about 5 GHz for microwave (MW) plasma treatment. The species of the plasma can damage the exposed surfaces and can diffuse into the exposed surfaces. The plasma treatment can also be called as a surface activation process configured to form dangling bonds on the surface of the beveled edge E1.

In some examples, the surface material of the first wafer 201 and the second wafer 202 may include a silicon-containing material, which may comprise silicon, silicon oxide, silicon nitride, silicon carbide, silicon oxynitride, silicon oxycarbide, silicon oxy-carbo-nitride, diamond, AlN, or the like. The plasma energy causes the breakage of the bonds of the surface material of the wafers 201 and 202, forming dangling bonds on silicon, which enable the formation of OH bonds in subsequent rinsing process and/or when the wafers 201 and 202 are exposed to air (which has moisture).

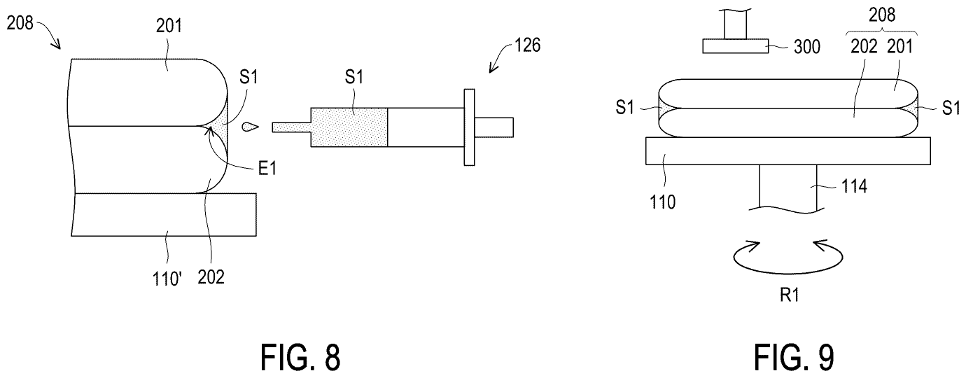

FIG. 12 illustrates a cross sectional view of a plasma injector according to some exemplary embodiments of the present disclosure. Referring to FIG. 7 and FIG. 12, in some embodiments, the plasma injector 122 includes an inner electrode 1221, a dielectric tube 1222, an outer electrode 1223, a nozzle 1224 and a power supply 1225 that runs at high voltages. The alternating voltage source shown in FIG. 1 is a commercial transformer maintained at about 20 kHz (maximum voltage of Vᵣₘₛ is about 15 kV) and is combined with two electrodes 1221, 1223. The inner electrode 1221 may be made of stainless steel and is wrapped with a quartz tube and a dielectric tube 1222. The outer electrode is a ground electrode and can be designed with a pencil-type, which is machined for the inner electrode 1221 with the dielectric tube 1222 to be interpolated. A diameter D1 of the nozzle 1224 substantially ranges from 5 mm to 1000 mm for injecting plasma gas therefrom. In the area of plasma production, in addition to being in contact with the outer electrode 1223, the end of the dielectric tube 1222 protrudes a predetermined distance (e.g., about 1 mm to 100 mm) as a discharge gap G1 for discharge against the end of the inner electrode 1221. The distance between the tips of the dielectric tube 1222 and the inner electrode 1221 is adjusted to control the discharge gap. The jet plasma gas is generated from a discharge inside the discharge gap G1.

In some embodiments, after the plasma injector 122 is aligned with the beveled edge E1, the plasma injector 122 is positioned such that the plasma gas may be injected along the beveled edge E1 between the first wafer 201 and the second wafer 202 as the supporting platform 110 is rotated. The rotation of the first wafer 201 and the second wafer 202 helps to provide uniform plasma treatment over the perimeter around the beveled edge E1 of wafer stack structure 208. In the present embodiment, a carrying surface of the supporting platform 110 and an injecting path of the plasma injector 122 are both oriented horizontally as shown in FIG. 7, but the disclosure is not limited thereto.

Referring to FIG. 8, then, a sealant material S1 is dispensed by a sealant dispenser 126 to fill the beveled edge E1 that has been through plasma treatment. The material used for sealant material S1 may include dielectric material such as polyimide, BCB, SOG, SiOₓ, SiNₓ, or SiONₓ, other inorganic materials, other silicon-related materials, other high thermal stable polymers, the like, or combination thereof. The sealant material S1 may include a high heat resistant material that has been applied and cured in a vacuum. It should be noted that the sealant material S1 is illustrated as a single layer for illustrative purposes and may include a plurality of layers of different materials. The sealant material S1 may be formed using spin-on, and hence is a spin-on dielectric (SOD) material. In an exemplary embodiment, the sealant material S1 includes perhydro-polysilazane (—(SiH₂NH)ₙ—). Since the sealant material S1 will be converted to silicon oxide in subsequent steps, it may also be referred to as a precursor. Perhydro-polysilazane is in a liquid form, and hence can fill the beveled edge E1 with no void formed.

In some embodiments, the sealant dispenser 126 may be disposed on another platform 110′. Accordingly, after the plasma treatment is performed, the wafer stack structure 208 may be transferred to the platform 110′ by the transfer apparatus, so the sealant dispenser 126 is positioned to inject sealant material S1 along the beveled edge E1 between the first wafer 201 and the second wafer 202 as the platform 110′ is rotated. The rotation of the first wafer 201 and the second wafer 202 helps to provide uniform dispensing of the sealant material S1, and also helps smooth and seal the sealant material S1 along the beveled edge E1 of wafer stack structure 208. However, in other embodiments, the sealant dispenser 126 may be integrated with the injection device 120. The disclosure is not limited thereto.

In some embodiments, the sealant material S1 at least partially fills the beveled edge E1 between the first wafer 201 and the second wafer 202. In the present embodiment, the sealant material S1 does not extend over edges of the first wafer 201 and the second wafer 202. In an embodiment, the sealant material S1 extends substantially to the outermost edge of the first wafer 201 and the second wafer 202, as is illustrated in FIG. 8. However, one of ordinary skill in the art will realize that one of the functions of the sealant material S1 is to provide structural support for the first wafer 201 during a subsequent thinning process. As such, it may not be necessary to extend the sealing layer 410 to the outermost edge of the first wafer 201 and the second wafer 202, dependent upon, among other things, the shape of the beveled edge E1, the thickness of the wafers, the amount to be thinned, the intended profile, the materials, and the like. In an embodiment, a curing process, which may be performed in a vacuum, is performed to remove any bubbles that may have been formed when applying the sealant material S1.

In some embodiments, a curing process may be performed over the sealant material S1 to cure the sealant material S1. In an embodiment, the curing process is performed at an elevated temperature. The curing temperature ranges from about 250 Celsius to about 350 Celsius. The curing time may be in the range between about 1 hour and 2.5 hours. During the process, H₂O is formed due to the breaking of OH bonds, and due to the reaction of the OH bonds with the H atom breaking from OH bonds. The O atom, which is bonded to a Si atom, is bonded to another oxygen atom that is generated due to the breaking of the OH bond. Si—O—Si bonds are thus formed. Eventually, with the help of the plasma treatment for forming dangling bonds on the surface of the beveled edge E1, the bonding strength between the sealant material S1 and the wafer stack structure 208 is significantly enhanced.

Then, referring to FIG. 9, a thinning process is performed on the first wafer 201 of the wafer stack structure 208 with the sealant material S1 filling the beveled edge E1. In some embodiments, the thinning process includes using a planarization apparatus 300 in a grinding process to reduce the thickness of the first wafer 201. One of ordinary skill in the art will realize that other thinning processes, such as a polish process (including a wet polish (CMP) and a dry polish), a plasma etch process, a wet etch process, or the like, may also be used. It should be noted that the thinning process is performed till the TSVs 213 (see FIG. 4) is exposed. In this manner, the TSVs 213 provide an electrical connection to circuitry included on the first wafer 201 through the second wafer 202. In some embodiments, the thinning process may be performed to thin the first wafer 201 until the sealant material S1 under the first wafer 201 is revealed.

As one of ordinary skill in the art will appreciate, the sealant material S1 provides additional support for the beveled edge E1 during the thinning process, thereby preventing or reducing cracking or chipping. As a result, higher yields may be obtained, reducing costs and increasing revenues. In other words, the sealant material S1 improves a robustness of the wafer stack structure 208 during the thinning process and/or subsequent operations performed to the wafer stack structure 208. By improving the robustness of the wafer stack structure 208, a likelihood of defects and/or yield loss within the wafer stack structure 208 due to trim-loss, trim wall exposure, and/or trim peeling that is inherent to a trimming operation may be reduced. Additionally, or alternatively and in some implementations, such a trimming operation is eliminated.

Referring to FIG. 10, after the thinning process is performed on the first wafer 201 a first thickness T1 of the first wafer 201a is thinner than a second thickness T2 of the second wafer 202. In some embodiments, the upper surface of the first wafer 201a is substantially coplanar with the upper surface of the sealant material S1. From a structural point of view, the first wafer 201a includes a planar upper surface 2011, a non-perpendicular rounded side surface 2012 connected between the planar upper surface 2011 and a lower surface 2013. The lower surface 2013 can also be seen as a bonding surface that is bonded to the second wafer 202. At this point, the manufacture of the wafer stack structure 208 is substantially done.

FIG. 11 illustrates an embodiment in which the processes described above are repeated multiple times to create stacked wafer configurations having three or more wafers in accordance with an embodiment of the present invention. In the embodiment illustrated in FIG. 11, a wafer stack structure 208′ having five wafers 202, 201a, 201b,201c, 201d is illustrated. The first wafer 201a and the second wafer 202 correspond to the corresponding wafers of FIG. 5 to FIG. 10, and the wafers 201b, 201c, 201d represent additional wafers that may be stacked on top of the first wafer 201a using a process similar to that discussed above with reference to FIG. 5 to FIG. 10. The plasma treatment and the sealant material S1 are respectively applied to the beveled edges E1 formed between any two adjacent wafers.

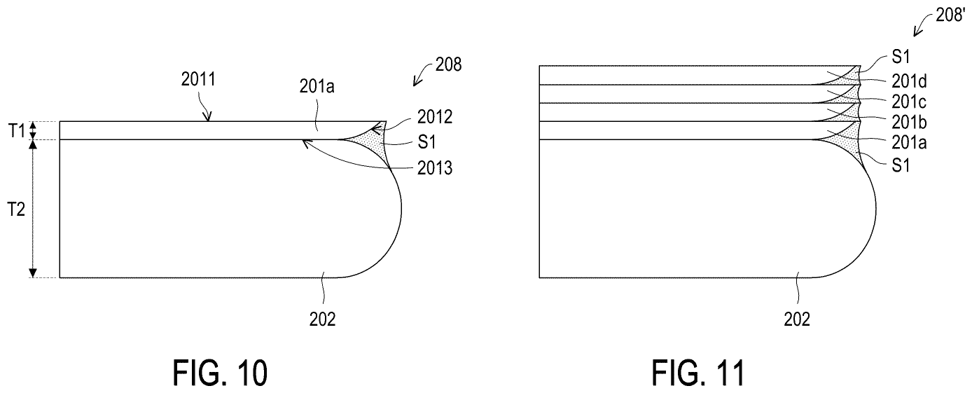

FIG. 13 illustrates a side view of a semiconductor processing apparatus according to some exemplary embodiments of the present disclosure. It is noted that the semiconductor processing apparatus 100a shown in FIG. 13 contains many features same as or similar to the semiconductor processing apparatus disclosed in the previous embodiments. For purpose of clarity and simplicity, detail description of same or similar features may be omitted, and the same or similar reference numbers denote the same or like components.

Referring to FIG. 13, in the present embodiment, the sealant dispenser 126 is integrated with the injection device 120a, so that the sealant dispenser 126 can be moved along with the edge detector 124 and the plasma injector 122. In this manner, after the edge detector 124 locates the beveled edge E1 of the wafer stack structure 208, the plasma injector 122 is moved by the transfer mechanism 125 to be aligned with the center of the beveled edge E1 for injecting the plasma gas toward the beveled edge E1 and performing plasma treatment. Then, the sealant dispenser 126 is moved by the transfer mechanism 125 to be aligned with the center of the beveled edge E1 for dispensing the sealant material to fill the beveled edge E1. In the embodiment, the transfer mechanism 125 may be a robot arm with 5 degrees of freedom, so as to align the plasma injector 122, the edge detector 124, and sealant dispenser 126 with the beveled edge E1 more precisely. For example, the transfer mechanism 125 can shift along x-axis, y-axis, z-axis, rotate between x-axis and y-axis (i.e., angle θ), and rotate between y-axis and z-axis (i.e., angle φ). In the embodiment, the carrying surface of the supporting platform 110 is oriented horizontally, so the injecting path of the plasma injector 122 and the dispensing path of the sealant dispenser 126 are all oriented horizontally.

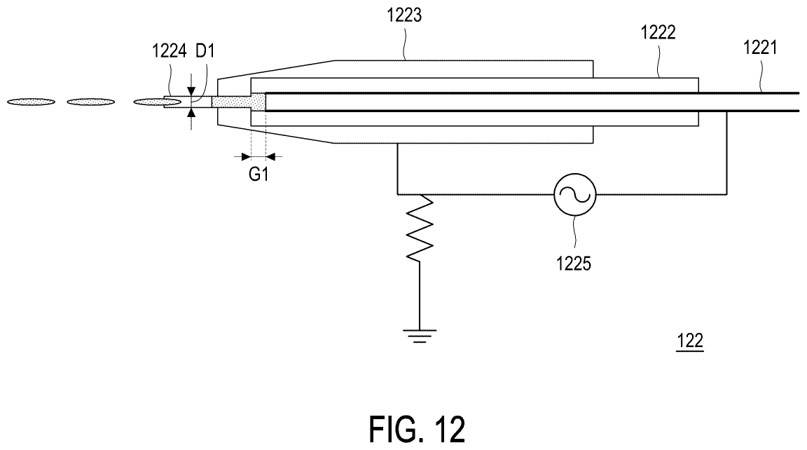

FIG. 14 illustrates a side view of a semiconductor processing apparatus according to some exemplary embodiments of the present disclosure. It is noted that the semiconductor processing apparatus 100b shown in FIG. 14 contains many features same as or similar to the semiconductor processing apparatus disclosed in the previous embodiments. For purpose of clarity and simplicity, detail description of same or similar features may be omitted, and the same or similar reference numbers denote the same or like components.

Referring to FIG. 14, in the present embodiment, the sealant dispenser 126 is integrated with the injection device 120b, so that the sealant dispenser 126 can be moved along with the edge detector 124 and the plasma injector 122. In the present embodiment, the carrying surface of the supporting platform 110 is oriented vertically, so the injecting path of the plasma injector 122 and the dispensing path of the sealant dispenser 126 are all oriented vertically. With such configuration, the plasma gas and the sealant material can easily travel to beveled edge E1 right underneath the nozzles of the plasma injector 122 and the sealant dispenser 126 due to gravity, so as to improve the process efficiency. In the embodiment, the transfer mechanism 125 may be a robot arm with 5 degrees of freedom, so as to align the plasma injector 122, the edge detector 124, and sealant dispenser 126 with the beveled edge E1 more precisely. For example, the transfer mechanism 125 can shift along x-axis, y-axis, z-axis, rotate between x-axis and y-axis (i.e., angle θ), and rotate between y-axis and z-axis (i.e., angle φ).

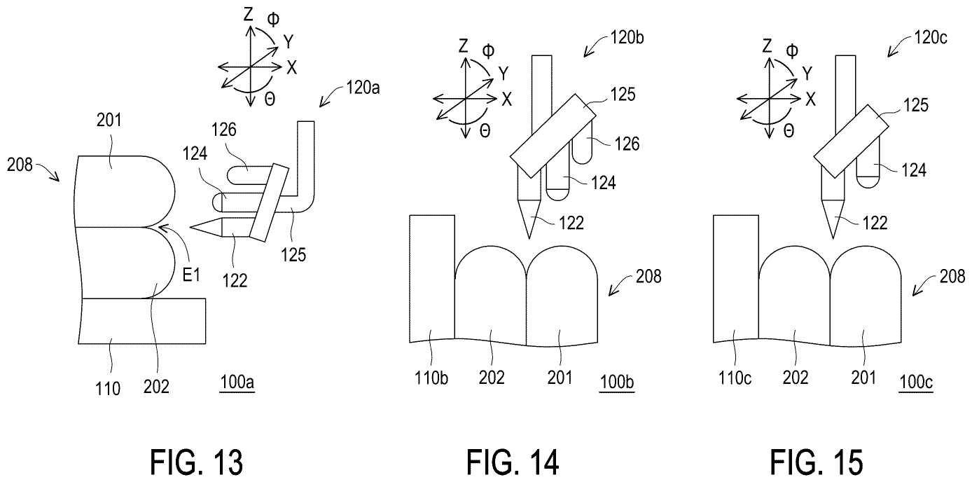

FIG. 15 illustrates a side view of a semiconductor processing apparatus according to some exemplary embodiments of the present disclosure. It is noted that the semiconductor processing apparatus 100c shown in FIG. 15 contains many features same as or similar to the semiconductor processing apparatus disclosed in the previous embodiments. For purpose of clarity and simplicity, detail description of same or similar features may be omitted, and the same or similar reference numbers denote the same or like components.

Referring to FIG. 15, in the present embodiment, the carrying surface of the supporting platform 110 is oriented vertically, so the injecting path of the plasma injector 122 is oriented vertically. With such configuration, the plasma gas can easily travel to beveled edge E1 right underneath the nozzle of the plasma injector 122 due to gravity, so as to improve the process efficiency. In the embodiment, the transfer mechanism 125 may be a robot arm with 5 degrees of freedom to align the plasma injector 122 and the edge detector 124 with the beveled edge E1 more precisely. For example, the transfer mechanism 125 can shift along x-axis, y-axis, z-axis, rotate between x-axis and y-axis (i.e., angle θ), and rotate between y-axis and z-axis (i.e., angle φ). In the present embodiment, the sealant dispenser 126 is not integrated with the injection device 120b, but may be disposed on another platform, so that the plasma treatment and the sealant material dispensing can be performed simultaneously over different wafer stack structures on different platforms.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a semiconductor processing apparatus includes a supporting platform configured to support a wafer stack structure comprising a first wafer bonded over a second wafer, and an injection device movably disposed above the supporting platform. The injection device includes an edge detector configured to locate a beveled edge between the first wafer and the second wafer, and a plasma injector coupled to the edge detector and configured to perform a plasma treatment over the beveled edge between the first wafer and the second wafer. In one embodiment, the semiconductor processing apparatus further includes a sealant dispenser configured to dispense a sealant material over the beveled edge to fill the beveled edge between the first wafer and the second wafer. In one embodiment, the sealant dispenser is integrated with the injection device to be moved along with the edge detector and the plasma injector. In one embodiment, the semiconductor processing apparatus further includes a transfer mechanism coupled to the injection device to move the injection device above the supporting platform. In one embodiment, the robot arm includes 5 degree of freedom robot arm. In one embodiment, the edge detector includes an image sensor configured to capture an image of the beveled edge. In one embodiment, the supporting platform further includes a rotating shaft to drive the supporting platform to rotate around the rotating shaft. In one embodiment, the semiconductor processing apparatus further includes a planarization tool configured to perform a thinning process over the first wafer. In one embodiment, a carrying surface of the supporting platform and an injecting path of the plasma injector are both oriented horizontally. In one embodiment, a carrying surface of the supporting platform and an injecting path of the plasma injector are both oriented vertically. In one embodiment, the plasma injector further includes a nozzle for injecting plasma gas therefrom, and a diameter of the nozzle substantially ranges from 5 mm to 1000 mm.

In accordance with some embodiments of the disclosure, a method of manufacturing a semiconductor package includes: bonding a first wafer over a second wafer to form a wafer stack structure; locating a beveled edge between the first wafer and the second wafer by an edge detector of an injection device; performing a plasma treatment by injecting plasma gas toward the beveled edge through a plasma injector of the injection device; and dispensing a sealant material by a sealant dispenser to fill the beveled edge between the first wafer and the second wafer; and performing a thinning process on the first wafer of the wafer stack structure with the sealant material filling the beveled edge. In one embodiment, the edge detector comprises an image sensor and locating the beveled edge further includes: capturing an image of the beveled edge by the image sensor; identifying a first inflection point of the first wafer and a second inflection point of the second wafer according to the image; and obtaining a center of the beveled edge according to the first inflection point and the second inflection point. In one embodiment, the plasma gas comprises clean dry air (CDA), nitrogen (N₂), oxygen (O₂), argon (Ar), or hydrogen (H₂). In one embodiment, the method of manufacturing the semiconductor package further includes: performing a curing process over the sealant material to cure the sealant material. In one embodiment, performing the thinning process comprises thinning the first wafer until the sealant material under the first wafer is revealed.

In accordance with some embodiments of the disclosure, a semiconductor package includes a first wafer bonded to a second wafer, a sealant material at least partially filling the beveled edge between the first wafer and the second wafer. A beveled edge is defined by an unfilled area between outer edges of the first wafer and the second wafer, and a first thickness of the first wafer is thinner than a second thickness of the second wafer. An upper surface of the first wafer is coplanar with an upper surface of the sealant material. In one embodiment, the sealant material comprises polyimide, BCB, SOG, SiOₓ, SiNₓ, or SiONₓ. In one embodiment, the first wafer comprise a planar upper surface, a non-perpendicular rounded side surface connecting the planar upper surface and a lower surface being bonded to the second wafer. In one embodiment, the sealant material does not extend over edges of the first wafer and the second wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing apparatus, comprising:
a supporting platform configured to support a wafer stack structure; and
an injection device movably disposed above the supporting platform and comprises an edge detector configured to locate a beveled edge between a first wafer and a second wafer, and a plasma injector coupled to the edge detector and configured to perform a plasma treatment over the beveled edge between the first wafer and the second wafer.

2. The semiconductor processing apparatus as claimed in claim 1, further comprising:
a sealant dispenser configured to dispense a sealant material over the beveled edge to fill the beveled edge between the first wafer and the second wafer.

3. The semiconductor processing apparatus as claimed in claim 2, wherein the sealant dispenser is integrated with the injection device to be moved along with the edge detector and the plasma injector.

4. The semiconductor processing apparatus as claimed in claim 1, further comprising a transfer mechanism coupled to the injection device to move the injection device above the supporting platform.

5. The semiconductor processing apparatus as claimed in claim 1, wherein the robot arm comprises 5 degree of freedom robot arm.

6. The semiconductor processing apparatus as claimed in claim 1, wherein the edge detector comprises an image sensor configured to capture an image of the beveled edge.

7. The semiconductor processing apparatus as claimed in claim 1, wherein the supporting platform further comprising a rotating shaft to drive the supporting platform to rotate around the rotating shaft.

8. The semiconductor processing apparatus as claimed in claim 1, further comprising a planarization tool configured to perform a thinning process over the first wafer.

9. The semiconductor processing apparatus as claimed in claim 1, wherein a carrying surface of the supporting platform and an injecting path of the plasma injector are both oriented horizontally.

10. The semiconductor processing apparatus as claimed in claim 1, wherein a carrying surface of the supporting platform and an injecting path of the plasma injector are both oriented vertically.

11. The semiconductor processing apparatus as claimed in claim 1, wherein the plasma injector further comprises a nozzle for injecting plasma gas therefrom, and a diameter of the nozzle substantially ranges from 5 mm to 1000 mm.

12. A method of manufacturing a semiconductor package, comprising:
bonding a first wafer over a second wafer to form a wafer stack structure;
locating a beveled edge between the first wafer and the second wafer by an edge detector of an injection device;
performing a plasma treatment by injecting plasma to the beveled edge through a plasma injector of the injection device; and
dispensing a sealant material by a sealant dispenser to fill the beveled edge between the first wafer and the second wafer.

13. The method of manufacturing semiconductor package as claimed in claim 12, wherein the edge detector comprises an image sensor and locating the beveled edge further comprises:
capturing an image of the beveled edge by the image sensor;
identifying a first inflection point of the first wafer and a second inflection point of the second wafer according to the image; and
obtaining a center of the beveled edge according to the first inflection point and the second inflection point.

14. The method of manufacturing the semiconductor package as claimed in claim 12, wherein the plasma gas comprises clean dry air (CDA), nitrogen (N₂), oxygen (O₂), argon (Ar), or hydrogen (H₂).

15. The method of manufacturing the semiconductor package as claimed in claim 12, further comprising:
performing a curing process over the sealant material to cure the sealant material; and
performing a thinning process on the first wafer of the wafer stack structure with the sealant material filling the beveled edge.

16. The method of manufacturing the semiconductor package as claimed in claim 12, wherein performing the thinning process comprises thinning the first wafer until the sealant material under the first wafer is revealed.

17. A semiconductor package, comprising:
a first wafer bonded to a second wafer, wherein a beveled edge is defined by an unfilled area between outer edges of the first wafer and the second wafer; and
a sealant material at least partially filling the beveled edge between the first wafer and the second wafer, wherein an upper surface of the first wafer is coplanar with an upper surface of the sealant material.

18. The semiconductor package as claimed in claim 17, wherein the sealant material comprises polyimide, BCB, SOG, SiOₓ, SiNₓ, or SiONₓ.

19. The semiconductor package as claimed in claim 17, wherein the first wafer comprise a planar upper surface, a non-perpendicular rounded side surface connecting the planar upper surface and a lower surface being bonded to the second wafer.

20. The semiconductor package as claimed in claim 17, wherein the sealant material does not extend over edges of the first wafer and the second wafer.
